(19) United States
(12) Patent Application Publication
(10) Pub. No.: US 2004/0067631 A1
(43) Pub. Date: Apr. 8, 2004

(54) Reduction of seed layer roughness for use in forming SiGe gate electrode

(76) Inventors: Haowen Bu, Plano, TX (US); Stephanie Watts Butler, Richardson, TX (US); Rajesh Khamankar, Coppell, TX (US); Hiroaki Niimi, Richardson, TX (US)

Correspondence Address: TEXAS INSTRUMENTS INCORPORATED, P O BOX 655474, M/S 3999, DALLAS, TX, 75265

(21) Appl. No.: 10/263,521

(22) Filed: Oct. 3, 2002

(51) Int. Cl. H01L 21/3205; H01L 21/4763

(52) U.S. Cl. 438/592

(57) ABSTRACT

Seed layer roughness can be reduced in conjunction with formation of a SiGe gate electrode. Surface characteristics of a gate dielectric can be modified, such by use of a nitrogen containing gas, prior to deposition of the seed layer on to the dielectric. The modifications in surface characteristics enable a thin seed layer to be formed overlying the gate dielectric with a reduced roughness relative to many conventional approaches.

### TECHNICAL FIELD

The present invention relates generally to integrated circuit fabrication and, more particularly, to reducing seed layer roughness for use in connection with formation of a silicon germanium (SiGe) gate electrode.

### BACKGROUND OF THE INVENTION

Polycrystalline silicon (polysilicon or poly-Si) is a common gate electrode material for metal-oxide-semiconductor (MOS) devices because it is easy to deposit and easy to dope. The polysilicon gate tends to exhibit increases in poly depletion effects in the scaling of the MOS structures, which can adversely affect operation of the resulting IC structure. As dielectric thickness decreases at a relatively constant gate bias, silicon surface potential (field) increases. As the surface potential increases, the electric field at the surface tends to deplete the poly-Si of carriers at the interface between poly-Si and gate dielectric, which produces a depletion capacitance.

This effect is known as poly depletion, and it is this effect that tends to lower expected drive current and results in reduced device speed due to a lower overall gate capacitance caused by the serial capacitance of poly depletion layer. Poly depletion can affect the stray capacitance associated with conventional MOS devices due to the poly-Si gate. These stray capacitances can aggregate with other stray capacitances, including those associated with the substrate, spacers, sidewalls, etc. to increase the overall stray capacitance of the structure. At least some of these other sources of stray capacitance are dependent upon device design and processing conditions.

As a result of possible limitations associated with poly-Si gate electrodes, efforts have increased in using other materials as gate electrodes. One approach is to replace the poly-Si gate electrode with a polycrystalline silicon germanium alloy (poly-SiGe) gate electrode. Poly-SiGe provides a promising alternative to poly-Si as the gate electrode material for MOS transistors because poly-SiGe can provide an added degree of threshold-voltage (VT) control, suppression of the gate-depletion effect for devices with thin gate oxides due to higher solubility of boron in Ge, as well as reduction of boron penetration through the gate dielectric from the electrode.

SiGe layers can be deposited on a silicon oxide gate dielectric layer, for example, by low-pressure chemical vapor deposition (LPCVD). This process, however, typically requires the predeposition of a silicon seed layer on which the poly-SiGe layer is deposited. The seed layer facilitates the subsequent deposition of the SiGe layer, as it helps prevent direct interaction between the germanium and the silicon oxide substrate. The reaction between germanium and silicon oxide, which can depend on the duration and temperature of the deposition potentially can result in accelerated island growth to the detriment of nucleation. Additionally, direct contact of Ge with silicon oxide could lead to charge-to-breakdown (Q_{BD}) degradation.

Conventional seed layer deposition processes tend to generate rough seed layers on the gate dielectric. Roughness in the seed layer can degrade device performance. For example, a rough seed layer can result in non-uniform Ge distribution in the seed layer, which can increase non-uniformities in VT microscopically across the wafer or batch process. Accordingly, efforts have been made in an attempt to reduce seed layer roughness.

For example, one conventional technique to generate a smoother seed layer includes increasing the thickness of the seed layer. When a thicker seed layer is used, VT still tends to be non-uniform. Additionally, the performance of the poly-SiGe electrode can be compromised due to the increased distance from the gate dielectric. Another approach is to reduce the seed layer growth rate, such as by increasing the seed layer deposition time. This other approach usually provides a limited reduction in roughness, especially when compared to the associated decrease in throughput if a single wafer process is used.

### SUMMARY OF THE INVENTION

The following presents a simplified summary of the invention in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

The present invention relates generally to reducing roughness of a seed layer utilized in formation of a SiGe gate electrode. The reduction in roughness is achieved by pre-treating a gate dielectric layer to modify surface characteristics of the substrate. For example, the surface modification can be implemented by annealing the gate dielectric layer in an ammonia environment or by other forms of nitridation. To facilitate depositing the seed layer, such as where the pre-treating and seeding are integrated in a common process chamber, the ammonia can be substantially evacuated from the process chamber prior to seeding.

A smoother seed layer, for example, could improve the uniformity associated with Ge, dopant and V_{T} distributions. The scheme can also enable a manufacturer to employ a thinner seed layer than typically used in most conventional approaches and yet still provide a sufficiently smooth seed layer.

### BRIEF DESCRIPTION OF THE DRAWINGS

The foregoing and other aspects of the present invention will become apparent to those skilled in the art to which the present invention relates upon reading the following description with reference to the accompanying drawings.

FIG. 1 is a schematic cross-sectional illustration of a transistor structure having a SiGe gate electrode structure in accordance with an aspect of the present invention.

FIG. 2 is a schematic cross-sectional illustration of a gate dielectric layer being processed in accordance with an aspect of the present invention.

FIG. 3 is a schematic cross-sectional illustration of the structure of FIG. 2 in which a seed layer is being formed in accordance with an aspect of the present invention.

FIG. 4 is a schematic cross-sectional illustration of the structure of FIG. 3 in which a SiGe layer is being formed over the seed layer in accordance with an aspect of the present invention.

FIG. 5 is a schematic cross-sectional illustration of the structure of FIG. 4 in which a cap layer is being formed over the SiGe layer in accordance with an aspect of the present invention.

FIG. 6 is a schematic cross-sectional illustration of a multi-layer SiGe gate electrode structure in accordance with an aspect of the present invention.

FIG. 7 is an example of a system that can be utilized to form at least part of a multi-layer SiGe gate electrode structure in accordance with an aspect of the present invention.

FIG. 8 is a flow diagram illustrating a methodology for forming a transistor having a SiGe gate electrode structure in accordance with an aspect of the present invention.

### DETAILED DESCRIPTION

The present invention relates generally to reducing roughness of a seed layer utilized in conjunction with formation of a SiGe gate electrode structure. The approach includes pre-treating a gate dielectric layer, such as with a gaseous medium (e.g., containing nitrogen) to modify surface characteristics of a gate dielectric layer prior to deposition of the seed layer on to the dielectric. For example, the pre-treating can include nitridation, such as annealing in an ammonia (NH₃) or deuterated ammonia (ND₃) environment, plasma treatment, or other surface treatment processes capable of modifying surface characteristics of the gate dielectric layer.

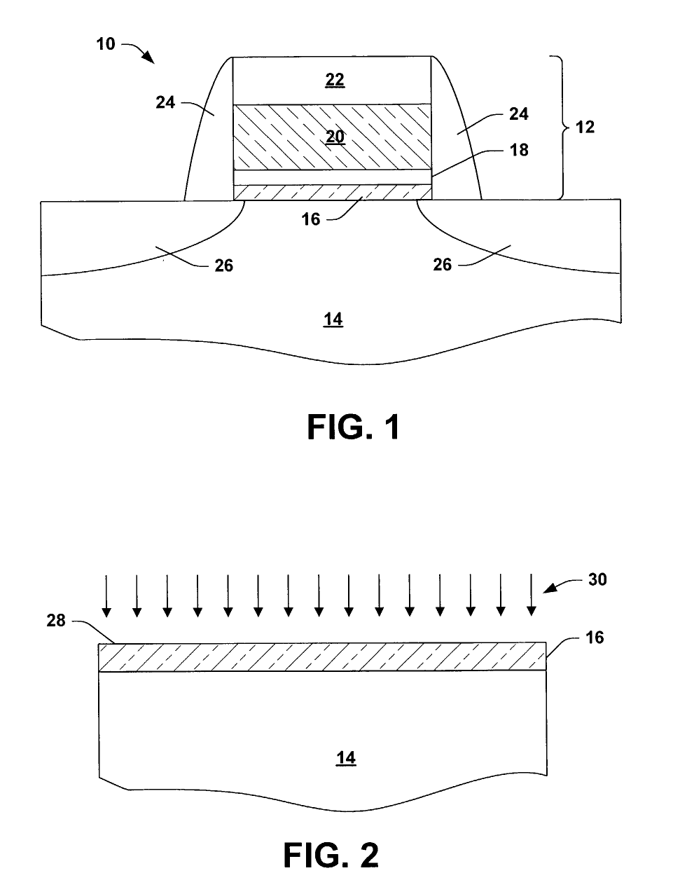

FIG. 1 illustrates a field effect transistor (FET) structure 10 having a gate electrode stack 12 in accordance with an aspect of the present invention. The FET structure 10 is fabricated on a substrate 14, such as silicon. A gate dielectric (or gate insulator or oxide) layer 16 is disposed on the substrate 14. The gate dielectric 16, for example, can be an oxide of silicon (e.g., silicon dioxide (SiO₂)) or a dielectric material having a dielectric constant (k) that is higher than SiO₂ (referred to herein as high-k materials).

A thin seed layer 18 is formed overlying the gate dielectric 16. In order to achieve a smoother seed layer 18, according to one or more aspects of the present invention, the gate dielectric 16 can be treated with a nitrogen containing gas prior to depositing the seed layer 18. The nitrogen affects the surface characteristic of the gate dielectric layer 16, such that the seed layer 18 can be applied more smoothly. For example, the pre-treating (e.g., by employing nitrogen during an annealing or nitridation process) may modify the exposed surface condition of the gate dielectric layer 16, which operates to increase areal bond density at the surface of the gate dielectric, as described herein. As a result of increasing the areal bond density at the surface of the gate dielectric, the seed layer 18 can be formed as a thinner layer having reduced tensile strain relative to conventional approaches. For example, the seed layer 18 is a thin layer of silicon less than about 100 angstroms (e.g., less than about 50 angstroms, namely, such as about 10-30 angstroms or less). The seed layer 18 deposited over the pre-treated gate dielectric layer 16 also tends to have fewer voids than typically associated with conventional seeding approaches.

A silicon germanium layer 20 is formed overlying the seed layer 18. The thin seed layer 18 thus mitigates direct contact of germanium (Ge) from layer 20 with the gate dielectric 16. Some Ge, however, from the layer 20 can diffuse into the silicon seed layer 18 during deposition of such layer as well as during the subsequent processing steps associated with formation of the SiGe gate electrode. The thin, substantially smooth seed layer 18 facilitates the inter-diffusion of Ge into the seed layer 18, which (due to a reduction in seed layer thickness) can be achieved at a generally reduced thermal budget relative to conventional approaches. The resulting SiGe layer 20 and seed layer 18 diffused with Ge can exhibit reduced poly-depletion effects.

A silicon cap layer 22 is disposed over the silicon germanium layer 20, such that the layers 16-22 comprise the gate electrode stack 12, which can be etched and processed to form the gate electrode of the transistor 10. Sidewall spacers 24 of a suitable insulating material can be disposed adjacent to the sidewalls of the gate electrode stack 12. Source/drain regions 26 can also be formed in the substrate 14. The source/drain regions 26 can include source/drain extensions that extend to regions generally aligned with and partially beneath the respective edges of the gate electrode stack 12, such as illustrated in FIG. 1. Those skilled in the art will understand and appreciate that the FET structure 10 can be utilized to make either P type or N type transistors. The source/drain regions 26 can be formed as N or P type regions by doping with boron, arsenic or other appropriate doping materials as known in the art.

It will be understood and appreciated by those skilled in the art that the seed layer 18 (diffused with Ge in the poly-SiGe stack) can be fabricated as a substantially thin, smooth layer due to pre-treating of the gate dielectric layer 16 prior to forming the seed layer 18. By enabling the thin, smooth seed layer, according to one or more aspects of the present invention, a more uniform threshold voltage V_{T} can be achieved across the wafer. In addition, poly-depletion effects associated with the electrode can be further reduced, thereby improving overall performance of the transistor 10. The gate electrode also tends to exhibit higher Q_{BD} relative to conventionally formed electrodes.

By way of example, FIGS. 2-6 depict partial cross-sectional views of a wafer at various stages in fabrication of a poly-SiGe gate electrode stack in accordance with an aspect of the present invention. Identical reference numbers are utilized in FIGS. 2-6 to refer to parts of the stack previously introduced with respect to FIG. 1.

FIG. 2 illustrates an example of pre-treatment being performed on the gate dielectric 16 layer in accordance with an aspect of the present invention. In this example, the gate dielectric 16 has been formed on the substrate 14. The gate dielectric material, for example, is silicon dioxide (SiO₂) or a suitable high-k dielectric material (e.g., where k>3.9). Examples of some high-k materials that could be utilized as the gate dielectric layer 16 include AlO₃, ZrO₂, AlHfO_{X}, HfO₂, La₂O₃ and Y₂O₃ to name a few. Those skilled in the art will understand and appreciate appropriate types of thermal oxidation or deposition techniques that can be employed to grow suitable structures to form gate dielectric layers, such as those identified above. It is to be further understood and appreciated that other materials also could be employed to form the gate dielectric layer 16.

After forming the gate dielectric layer 16, an exposed surface 28 of the gate dielectric 16 is pretreated, indicated at 30, by modifying surface characteristics of the gate dielectric. For example, the surface 28 of the gate dielectric can be pretreated with a gaseous medium at a high temperature, such as via nitridation. Nitridation can include annealing in an ambient containing nitrogen (e.g., any environment containing at least some nitrogen). Nitridation provides a source of atomic nitrogen that can be extracted at the elevated annealing temperature.

By way of example, a nitridation pre-treatment 30 can include annealing in an NH₃ or ND₃ environment at a temperature greater than about 500° C. Such annealing can be implemented by providing NH₃ or ND₃ at about 500-4000 standard cubic centimeters per minute (SCCM) and at a temperature in a range from about 600 to about 900° C. As an alternative example to NH₃ or ND₃ annealing, for example, the pre-treatment 30 applied to the surface structure of the gate dielectric layer 16 can include other types of nitridation, such as with nitric oxide (NO) or nitrous oxide (N₂O). Another alternative type of pre-treatment 30 is to utilize plasma nitridation or other types of plasma treatment for modifying surface characteristics of the gate dielectric layer 16. For example, plasma nitridation can be utilized by employing a plasma nitridation system, such as available from Applied Materials, Inc. of Santa Clara, Calif., or ASM International N.V. of the Netherlands, or from Tokyo Electron Limited of Tokyo, Japan.

Because the pre-treatment 30 (e.g., with NH₃, ND₃ or other nitrogen-containing gas) can be implemented in the same processing chamber (and/or cluster) utilized to form the seed layer 18 (and possibly the preceding gate dielectric layer 16 or subsequent layers of the poly-SiGe stack), those skilled in the art will appreciate that such pre-treatment can be efficiently and economically integrated into the poly-SiGe stack deposition process. Alternatively, the pre-treatment and the subsequent seeding process can be carried out in separate chamber on a common cluster. Those skilled in the art will also understand and appreciate that the nitridation or annealing could be implemented after formation of the gate dielectric layer 16 or, alternatively, during a latter part of forming the gate dielectric layer in accordance with an aspect of the present invention.

The nitrogen from the ammonia or other type of pre-treatment 30 interacts with the surface 28 of the gate dielectric layer 16. Such interaction, for example, may modify the surface structure of the gate dielectric layer 16. The surface modifications, which may include an increase in the areal bond density of the material forming the gate dielectric layer 16, may operate to reduce the tensile strain of the subsequently applied seed layer 18.

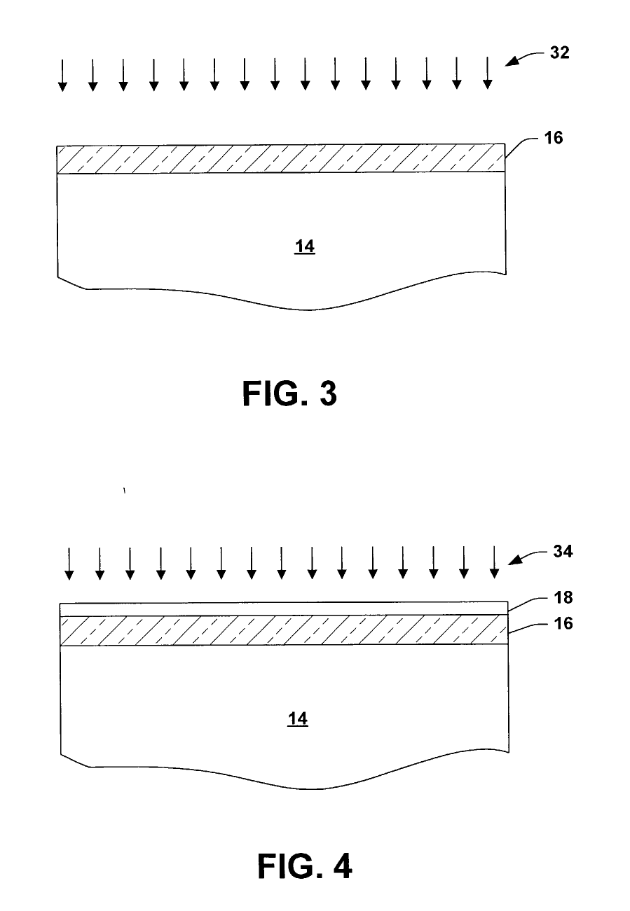

Turning to FIG. 3, after pre-treating the gate dielectric 16, a thin and substantially smooth silicon seed layer is formed by depositing a silicon material on to the gate dielectric layer, as indicated at 32. For example, the silicon material 32 could be deposited via CVD using silane (SiH₄) or disilane (Si₂H₆) with nitrogen (N₂) or hydrogen (H₂) carriers at about 450 to 650° C. By way of example, the seed layer deposition can occur in a reduced pressure atmosphere of about 100 torr at about 550° C., with the silane 32 provided at about 100 SCCM in a nitrogen (N₂) carrier environment. By way of alternative example, the seed layer could also be deposited using silane at about 100 SCCM in an H₂ carrier environment pressurized to about 1 atm. Those skilled in the art will understand and appreciate other possible deposition conditions that can be utilized to form the resulting seed layer 18, as depicted in FIG. 4.

As mentioned above, the pre-treatment of the gate dielectric layer 16 can operate to mitigate the tensile strain of seed layer 18 at the interface between layers 16 and 18. It is believed that the reduction in tensile strain of the seed layer 16 is attributed, at least in part, to reducing the difference in the areal bond densities between the seed layer 18 and the dielectric layer 16. It will be further appreciated that the amount of reduction in tensile strain on the seed layer 18 due to pre-treating the gate dielectric depends, at least in part, on the thickness of the seed layer. Thus, for a given pre-treatment to the gate dielectric layer 16, the reduction in tensile strain of the seed layer 18 becomes more pronounced as a thinner seed layer is utilized, such as having a thickness less than about 50 angstroms (e.g., 10-30 angstroms). Therefore, the pre-treatment enables a thinner and smoother seed layer to be utilized in formation of a poly-SiGe stack 12 in accordance with an aspect of the present invention. The seed layer 18 formed over the pre-treated gate dielectric 16 also usually has fewer voids, which further mitigates direct contact between Ge the gate dielectric layer.

Those skilled in the art will understand and appreciate that the use of a thinner and smoother seed layer 18 helps to improve doping activation at the electrode/gate dielectric interface and, therefore, poly depletion effects are reduced. Additionally, a thinner and smoother seed layer facilitates the inter-diffision of Ge into the seed layer, which advantageously can occur with lower thermal energy than most conventional approaches.

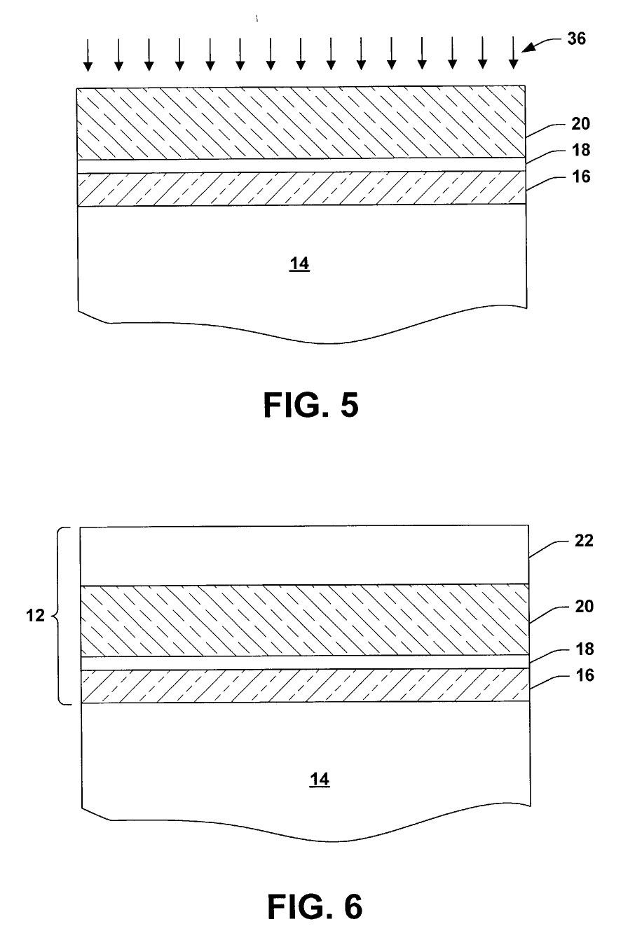

After forming the thin seed layer 18, as shown in FIG. 4, silane and germane (GeH₄), indicated at 34, can be deposited overlying the seed layer 18 to form the silicon germanium SiGe layer 20 (FIG. 5). For example, the silane and germane can be deposited with N₂ or H₂ carriers at a temperature of about 450° C. to about 650° C. so as to form the SiGe layer having a desired thickness (e.g., about 500 to about 1000 angstroms). Because the seed layer 18 can be substantially thin (e.g., <50 angstroms), inter-diffusion of Ge with the seed layer during such deposition 34 is facilitated. When the SiH₄ is replaced with another Si source gas that has a faster deposition rate than that of SiH₄, the separate seeding step may be unnecessary. This is because a thin Si seed layer can be formed at the beginning of the SiGe deposition step, thereby further improving efficiency of the process in accordance with an aspect of the present invention.

Turning to FIG. 5, after the SiGe layer 20 has been formed, an optional silicon cap layer 22 (FIG. 6) can be formed by further deposition of silicon 36. For example, the deposition 36 can include silane with N₂ or H₂ carriers at a process temperature in a range of about 450° C. to about 700° C. The deposition 36 can be performed so as to form the silicon cap layer 22 having a thickness of about 0 to about 1,000 angstroms (e.g., approximating the thickness of the SiGe layer) depending on the total SiGe stack thickness desired such as shown in FIG. 6. Also, the silicon cap layer may be unnecessary if particular metals are used to form silicide that overlays the SiGe stack.

FIG. 6 illustrates layers 14, 16, 18, 20 and 22 that can be further processed to form a transistor structure, such as shown in FIG. 1. The layers 16, 18, 20 and 22 define a poly-SiGe stack in accordance with an aspect of the present invention. Those skilled in the art will understand and appreciate various processing operations that can be utilized in formation of FETs in accordance with an aspect of the present invention. By way of example, the SiGe stack can be patterned via photolithography and etched (e.g., via an etch chemistry or plasma etching) to form the gate electrode structure. Ion implantation or other doping techniques can be utilized to form source/drain regions 26 (FIG. 1) and associated source/drain electrodes. The type and amount of doping can be varied according to the type of device structure desired. It further is to be appreciated that the gate electrode structure 12 can be used in the formation of CMOS, BiCMOS or HBT devices.

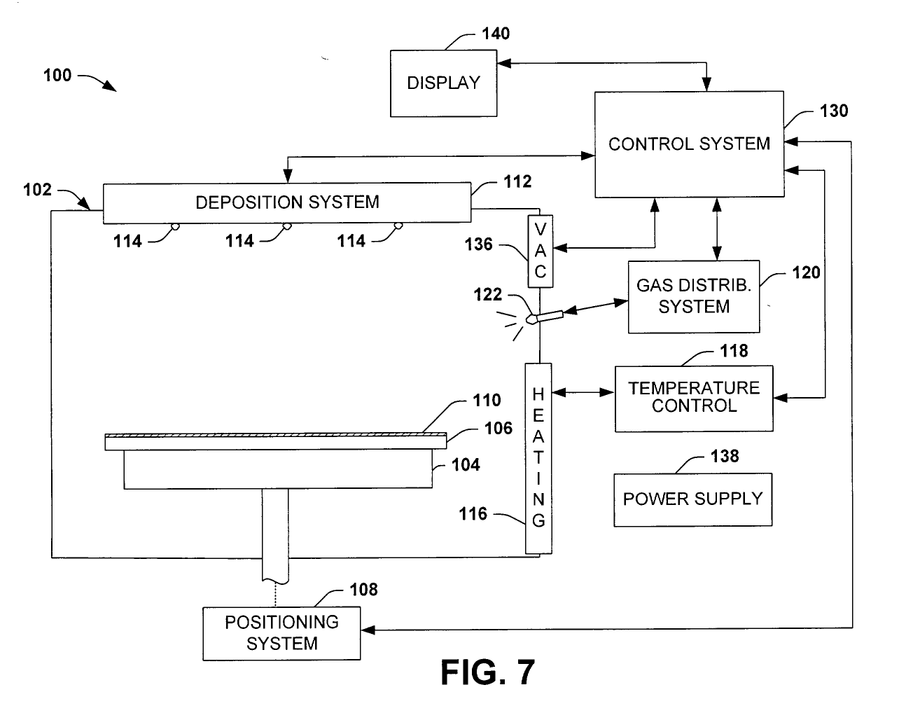

FIG. 7 illustrates an example of a system 100 operative to form at least a portion of a SiGe gate electrode stack in accordance with an aspect of the present invention. In this example, it is assumed that the system 100 forms the layers of the gate electrode via deposition, such as CVD. Examples of CVD processes that may be utilized to form the respective layers, in accordance with an aspect of the present invention, include Low Pressure CVD (LPCVD), Plasma Enhanced CVD (PECVD), and Rapid Thermal CVD (RTCVD). It is to be appreciated, however, that the present invention is applicable to other types of thin film formation, such as other deposition techniques (e.g., Physical Vapor Deposition (PVD)) and film growth techniques.

The system 100 includes a process chamber 102 that includes a support 104, such as may include a stage (or chuck) operative to support a substrate 106, such as a wafer. A positioning system 108 is operatively connected to the support 104 for positioning the stage at a desired position within the chamber 102. The system 108 could also provide for rotation of the substrate within the chamber 102 to facilitate generally uniform deposition of materials on the substrate 106. It is to be appreciated that wafer positioning systems 108 are evolving and that any such system could be used.

As depicted in FIG. 7, for example, a thin gate dielectric layer 110 has already been formed on the substrate 106, such as through thermal oxidation, plasma oxidation or deposition of desired materials. Such deposition can occur in the chamber 102 or in another associated chamber, for example, which can be part of the same or a different cluster.

The system 102 includes a deposition system 112 for forming a layer of desired material on the substrate 106. The deposition system is coupled to a source of deposition materials (e.g., supply of gaseous silicon), such as for use in forming a silicon seed layer. The deposition system 112 includes gas inlets 114 that are controlled to spray the gaseous materials on to the wafer 106 at a desired gas flow rate as part of the deposition process. The gases flowing into the process chamber 102 can be controlled with electronic mass flow controllers (not shown) and the chamber pressure can be controlled with a throttle valve.

Temperature also can be maintained within the chamber by one or more heating elements 116 operative to heat the contents of the chamber 102 to within a desired temperature range. For example, a temperature control module 118 is coupled to control the heating elements 116 to maintain process-dependent temperatures at different stages of processing.

Additionally, a gas distribution system 120 is in fluid communication with the chamber 102 for selectively providing a gaseous medium into the chamber according to process requirements. For example, the gas distribution system 120 includes a source of a nitrogen-containing gaseous medium that is to be provided into the chamber 102 for pre-treating the gate dielectric layer 110 overlying the substrate 106. The nitrogen-containing gas can be provided into the chamber 102, for example, through a nozzle, indicated at 122. While, for purposes of illustration, a single nozzle 122 is shown in FIG. 7, it is to be appreciated that more than one nozzle or other gas delivery mechanisms can be utilized to provide gas into the chamber 102 in accordance with an aspect of the present invention. It also will be appreciated that the nozzle(s) 122 can be located at any position to facilitate interaction between the gas and the surface of the gate dielectric layer 110.

As described herein, the gas distribution system 120 can be configured to provide NH₃ or ND₃, for example, at a rate of about 500 to about 4000 SCCM, which in the heated chamber 102 can modify surface characteristics of the gate dielectric layer 110. Alternatively, the gas distribution system can be configured to provide nitridation relative to the surface of the gate dielectric, such as plasma nitridation or nitridation via other nitrogen containing gases (e.g., NO, NO₂), for example. Small amounts of nitrogen could incorporate into the gate dielectric layer 110; although usually at sufficiently low concentrations so as to mitigate possible negative consequences when compared relative to the benefits associated with subsequent application of the Si seed layer.

By way of further example, the integrated system 100 includes control system 130 that can be programmed and/or configured to control the positioning system 108, deposition system(s) 112, heating element 116, and gas distribution system 120. Those skilled in the art will understand various ways in which the control system 130 can be programmed to implement desired control of the process conditions within the chamber 102.

By way of example, the control system can control the gas distribution system 120 and heating elements 116 so as to provide the nitrogen-containing gas (e.g., NH₃ or ND₃) at a desired flow rate (e.g., about 500 SCCM to about 4000 SCCM) while concurrently maintaining a desired temperature (e.g., in a range from about 600° C. to about 900° C.) within the chamber 102 to pre-treat the dielectric layer 110 in accordance with an aspect of the present invention. After pre-treating the dielectric layer 110 and before forming the subsequent seed layer, the control system 130 can control a vacuum system 136 to substantially completely evacuate the nitrogen-based gas provided during pre-treatment of the dielectric layer 110. The control system 130 can then control the deposition system to deposit silicon for forming a thin seed layer overlying the pretreated gate dielectric layer 110, such as described herein.

The example used herein depicts a single wafer reactor system 100. However, the instant invention can also be carried out in a batch furnace. Those skilled in the art will understand and appreciate various types and configurations of reactor systems that could be utilized to implement a methodology in accordance with one or more aspects of the present invention.

A power supply 138 provides operating power to the system 100. Any suitable type of power supply (e.g., battery, line power) may be employed to carry out the present invention. The system 100 further can include a display 140 operatively coupled to the control system 130 for displaying a representation (e.g., graphical and/or text) of one or more process parameters corresponding to operating conditions within the chamber (e.g., temperature, pressure, gas flow rates, etc.) or to wafer characteristics (e.g., film thickness), which can be monitored in situ.

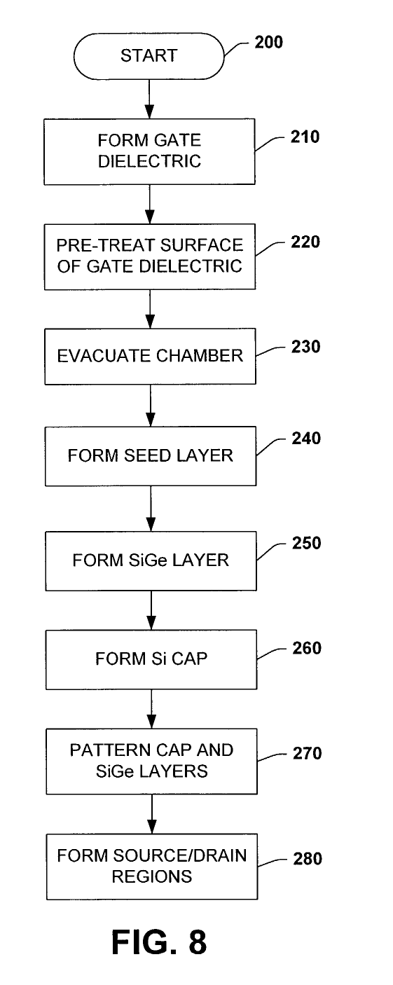

In view of the foregoing structural and functional features described above, methodologies for fabricating a SiGe gate electrode stack in accordance with an aspect of the present invention will be better appreciated with reference to FIG. 8. Those skilled in the art will understand and appreciate that not all illustrated features may be required to implement a methodology in accordance with an aspect of the present invention. While, for purposes of simplicity of explanation, the methodology of FIG. 8 is shown and described as being implemented serially, it is to be understood and appreciated that the present invention is not limited to the illustrated order, as some parts of the methodology could, in accordance with the present invention, occur in different orders or concurrently with other parts from that shown and described.

FIG. 8 illustrates a methodology for fabricating a transistor structure according to an aspect of the present invention. The methodology begins at 200 such as in connection with providing and preparing a substrate material, such as silicon. At 210, a gate dielectric is formed overlying the substrate. The gate dielectric, for example, can be silicon dioxide; although, other types of gate dielectrics also can be utilized, such as high k materials, for example.

At 220, an exposed surface of the gate dielectric formed at 210 is pre-treated in accordance with an aspect of the present invention. Such pre-treating can include, for example, NH₃ or ND₃ annealing, nitridation or plasma treatment with nitrogen. The nitrogen in the pre-treating (220), for example, may increase the aerial bond density on the gate dielectric side, which tends to reduce the tensile strain associated with a subsequently applied silicon seed layer, such as when applied at a thickness less than about 50 angstroms, for example. It is to be appreciated that some of the nitrogen in the pre-treating may be incorporated into the gate dielectric and form oxynitride (SiNₓO_{y}). However, the percentage of nitrogen actually incorporated into the gate dielectric is sufficiently small, such that the benefits in the resulting SiGe electrode structure should outweigh the possible minimal negative consequences associated therewith.

By way of example, the pre-treating can include NH₃ or ND₃ annealing at about 500 to 4000 SCCM at about 600° C. to about 900° C. After pre-treating the surface at 220, the processing chamber is evacuated of the nitrogen containing gas at 230. At 240, the seed layer is deposited over the modified gate dielectric. Due to the pre-treating at 220, the seed layer can be substantially thin, such as less than about 50 angstroms (e.g., in a range from about 10-30 angstroms or less). Those skilled in the art will appreciate that even such a substantially thin seed layer is substantially smooth and that formation or islands or voids in the seed layer is mitigated.

By way of further example, for seed layer deposition of SiH₄ at about 100 SCCM in N₂ carrier, at 100 torr and about 550° C., the smoothness of the seed layer (measured via atomic force microscopy (AFM) as a RMS value in angstroms) can decrease from an RMS of about 9 angstroms (for a conventional process) to an RMS of about 3 angstroms (where seeding is preceded by pre-treating). Depending on the underlying gate dielectric, in another example of seed layer deposition, using SiH₄ at a flow rate of about 100 SCCM in an N₂ carrier environment, a conventional approach without pre-treating yielded an RMS value of about 10 angstroms, whereas a seed layer preceded by NH₃ annealing provided an RMS value of about 7 angstroms. In yet another example of seed layer deposition process, using SiH₄ at a flow rate of about 100 SCCM in an H₂ carrier environment, a conventional approach without pre-treating yielded an RMS value of about 16 angstroms, whereas a seed layer preceded by plasma nitridation of a SiO₂ gate dielectric layer can result in an RMS value of about 8 angstroms.

At 250 a SiGe layer is formed, such as by depositing SiGe over the silicon seed layer. As mentioned above, instead of employing a separate seed layer formation step (240), a thin Si seed layer can be formed at the beginning of the SiGe deposition step 250. Some of the Ge can diffuse into the seed layer during the deposition as well as during subsequent processing steps. It will be appreciated that the Ge diffusion into the Si seed layer is facilitated due to the reduced roughness and thickness of the seed layer enabled by the pre-treatment (220). For example, the SiGe layer can be deposited as a combination of SiH₄ and GeH₄ in an N₂ or H₂ carrier environment heated at a temperature in a range from about 450° C. to about 650° C. The SiGe layer can have a thickness of about 200 to about 1,000 angstroms.

At 260, a silicon cap is formed over the SiGe layer formed at 250. The cap layer can be formed over the SiGe layer, for example, by depositing SiH₄ in an N₂ or H₂ carrier environment at a temperature ranging from about 450° C. to about 600° C. The thickness of the cap can be in a range in from about 0 to about 1,000 angstroms, depending on the total SiGe stack thickness desired such as shown in FIG. 6. Also, the silicon cap layer may be unnecessary if particular metals are used to form silicide that overlays the SiGe stack.

The formation of the layers at 210-260 can be implemented within an integrated deposition system, for example. In particular, the pre-treating at 220 and formation of the seed layer 240 can be integrated within a single processing chamber and cluster in accordance with an aspect of the present invention.

At 270, the cap and SiGe layers are patterned and etched to form a corresponding SiGe stack for use as a gate electrode in a transistor. An insulating layer can also be applied over the gate electrode structure. Those skilled in the art will understand and appreciate various techniques and chemicals that can be utilized to form a desired gate electrode structure from the layers formed at 210-260.

At 280, source/drain regions are formed for the transistor. This can include doping the transistor structure with suitable ions (e.g., boron, arsenic), such as by ion implantation or other doping techniques. The formation of the source/drain regions can also include forming appropriate source/drain extension regions generally aligned with lateral edges with the edges of the gate electrode formed at 270.

Those skilled in the art will understand that the foregoing methodology can be employed in connection with CMOS, BiCMOS and HBT technologies, to name a few. Additionally because the pre-treatment at 220 can be performed in the same process chamber as seed layer formation at 240, the methodology can be performed efficiently and economically. It further is to be appreciated that transistors on a wafer formed according to such methodology should exhibit improved, more uniform V_{T} characteristics as well as have reduced poly-depletion effects. The gate electrode structure fabricated according to an aspect of the present invention also enables enhanced Q_{BD} characteristics (e.g., an increase in Q_{BD}).

What has been described above includes examples and implementations of the present invention. Because it is not possible to describe every conceivable combination of components, circuitry or methodologies for purposes of describing the present invention, one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A fabrication method to reduce roughness of a seed layer for use in a gate electrode, comprising:
pre-treating a surface of a gate dielectric layer associated with the gate electrode; and
forming a seed layer overlying the pre-treated surface of the gate dielectric layer.

2. The method of claim 1, further comprising providing a substrate and forming the gate dielectric layer overlying an exposed surface of the substrate.

3. The method of claim 2, the gate dielectric layer comprising at least one of silicon dioxide (SiO₂) and a material having a dielectric coefficient that exceeds SiO₂.

4. The method of claim 2, further comprising forming a silicon germanium (SiGe) layer overlying the seed layer.

5. The method of claim 4 implemented as part of a transistor fabrication process, the transistor fabrication process, further comprising:
forming a gate dielectric stack that includes at least the gate dielectric layer, the seed layer, and the SiGe layer; and
forming source and drain regions in the substrate generally aligned relative to edges of the gate dielectric stack.

6. The method of claim 1, the pre-treating further comprising annealing the surface of the gate dielectric layer in a nitrogen containing gas.

7. The method of claim 6, the annealing further comprising annealing with one of ammonia (NH₃) and deuterated ammonia (ND₃) at a temperature greater than about 500° C.

8. The method of claim 1, further comprising employing nitridation to pre-treat the gate dielectric layer.

9. The method of claim 8, the nitridation further comprising plasma nitridation.

10. The method of claim 1, the formation of the seed layer further comprising forming a Si seed layer overlying the pre-treated gate dielectric so as to have a thickness less than or equal to about 50 angstroms.

11. The method of claim 10, the formation of the Si seed layer further comprising depositing SiH₄ overlying the pre-treated gate dielectric at a flow rate of greater than about 50 stand cubic centimeters per minute.

12. The method of claim 10, the Si seed layer having a thickness that is less than or equal to about 30 angstroms.

13. The method of claim 1, the pre-treating of the gate dielectric layer and the formation of the seed layer being performed consecutively as an integrated process in at least one of a common process chamber and cluster.

14. A method for fabricating layers for use in formation of a silicon germanium (SiGe) gate electrode, comprising:
providing a substrate having a first surface;
forming a gate dielectric layer overlying the first surface of the substrate;
treating the gate dielectric layer with a gaseous medium to modify a surface characteristic of the gate dielectric;
forming a seed layer overlying the treated gate dielectric, whereby the treating mitigates roughness of the seed layer; and
forming a SiGe layer overlying the seed layer, such that germanium (Ge) interdiffuses into the seed layer.

15. The method of claim 14, the gate dielectric layer comprising at least one of silicon dioxide (SiO₂) and a material having a dielectric coefficient that exceeds SiO₂.

16. The method of claim 14, the treating further comprising annealing the surface of the gate dielectric layer in process chamber in a nitrogen-containing gaseous medium.

17. The method of claim 16, the annealing further comprising annealing with one of NH₃ and ND₃ at a temperature greater than about 550° C.

18. The method of claim 14, further comprising employing nitridation to treat the gate dielectric layer.

19. The method of claim 14, the formation of the seed layer further comprising forming the seed layer by depositing silicon overlying the pre-treated gate dielectric so as to form the seed layer having a thickness less than or equal to about 50 angstroms.

20. The method of claim 19, the formation of the Si seed layer further comprising depositing SiH₄ overlying the pre-treated gate dielectric at a flow rate of greater than about 50 SCCM and at a temperature in a range from about 450° C. to about 650° C.

21. The method of claim 19, the Si seed layer having a thickness that is less than or equal to about 30 angstroms.

22. The method of claim 14, the treating of the gate dielectric layer and the formation of the seed layer being performed consecutively as an integrated process in at least one of a common process chamber and a cluster.

23. The method of claim 22, further comprising evacuating the process chamber after the treating of the gate dielectric layer.

24. The method of claim 14 implemented as part of a transistor fabrication process, the transistor fabrication process, further comprising:
forming a gate dielectric stack that includes the gate dielectric layer, the seed layer, and the SiGe layer; and
forming source and drain regions in the substrate generally aligned relative to respective edges of the gate dielectric stack.

25. The method of claim 24, further comprising, prior to forming the gate dielectric stack, forming a cap layer overlying the SiGe layer, such that the formation of the gate dielectric stack also includes the cap layer.

26. A processing system for use in forming at least part of a gate electrode stack on a silicon substrate, comprising:
means for pre-treating an exposed surface of a gate dielectric layer overlying the substrate so as to modify a surface characteristic of the gate dielectric layer; and
means for forming a seed layer overlying the pre-treated surface of the gate dielectric layer, whereby roughness of the seed layer is mitigated based on pre-treatment of the gate dielectric layer provided by the means for pre-treating.
